(19) United States
(12) Patent Application Publication
(10) Pub. No.: US 2001/0051419 A1
(43) Pub. Date: Dec. 13, 2001

(54) METHOD FOR FABRICATING A MOSFET HAVING POLYCIDE GATE ELECTRODE

(76) Inventors: SE AUG JANG, ICHON-SHI (KR); TAE KYUN KIM, ICHON-SHI (KR)

Correspondence Address: JACOBSON PRICE HOLMAN & STERN, PROFESSIONAL LIMITED LIABILITY COMPANY, 400 SEVENTH STREET N W, WASHINGTON, DC, 20004

(21) Appl. No.: 09/327,519

(22) Filed: Jun. 8, 1999

(30) Foreign Application Priority Data
Jun. 29, 1998 (KR) 1998-24653

(51) Int. Cl. H01L 21/3205; H01L 21/4763

(52) U.S. Cl. 438/592

(57) ABSTRACT

It is an object of the present invention to provide a method for forming a semiconductor MOSFET device having polycide gate electrode by preventing the sidewall screen oxide from being abnormally formed, and according to an aspect of the present invention, there is provided a method for fabricating a MOSFET comprising a polycide gate electrode with titanium silicide on a semiconductor substrate, comprising the steps of: forming a polysilicon layer and a titanium layer on a gate insulating layer; performing a rapid thermal process for forming a titanium silicide layer under nitrogen-filled environment; and removing a titanium nitride layer, which is a byproduct formed on the titanium silicide layer during said b) step of performing the rapid thermal process.

### FIELD OF THE INVENTION

The present invention relates to a method for fabricating a semiconductor device, particularly to a Metal-Oxide Semiconductor Field Effect Transistor(“MOSFET”) having a polycide gate electrode.

### BACKGROUND OF THE INVENTION

For a conventional MOSFET, a polysilicon or a polycide, consisting of stacked tungsten silicide(WSi₂) and polysilicon, is used as a gate electrode. As the integration density of semiconductor devices are increased, the dimension of the gate electrode is decreased, so that it is impossible to satisfy the value of resistance required for the high density devices with the above mentioned conventional gate electrode materials.

Thus, it is suggested to use silicide materials such as TiSi₂, CoSi₂, VSi₂, CrSi₂, ZrSi₂, NbSi₂, MoSi₂, HfSi₂, etc. for gate electrode. As a result of the researches for those silicide materials, the titanium silicide(TiSi₂) is regarded as promising because TiSi₂ satisfies the requirements of low resistance, high melting point, easiness of thin film formation and patterning, thermal stability, etc.

Referring to FIGS. 1a to 1f, there is shown a process flow of conventional method for forming the conventional MOSFET using TiSi₂ as the gate electrode. As shown in FIG. 1a, a gate oxide layer 2 is formed on a silicon substrate 1. A low resistance polysilicon layer 3 is formed on the gate oxide layer 2 by Low Pressure Chemical Vapor Deposition(“LPCVD”) and then a titanium(Ti) layer 4 is formed on the polysilicon layer 3.

As shown in FIG. 1b, a titanium silicide(TiSi₂) layer 5 is formed by Rapid Thermal Process(“RTP”) making the polysilicon layer 3 and the titanium layer 4 reactive. Then, as shown in FIG. 1c, an oxide layer 6 is formed on the titanium silicide layer 5 in order to protect the titanium silicide layer 5 while forming an oxide spacer(not shown) afterward. A gate electrode is patterned by masking and etching processes, as shown in FIG. 1d. Then, a screen oxide layer 7 is formed on the exposed semiconductor substrate 1 by thermal oxidation process in order to protect the surface of the semiconductor substrate during ion doping process for source or drain. Finally, FIG. 1f shows a lightly doped source or drain region 8 for Lightly Doped Drain(“LDD”) FET is formed by low density ion doping.

Although not shown in the FIG. 1, after forming the lightly doped source or drain, a spacer is formed on the sidewall of the gate electrode, and a highly doped source or drain is formed by ion implantation.

FIGS. 2a to 2c show the problem of the above mentioned conventional method for forming the titanium silicide gate electrode. As shown in FIG. 2a, a titanium nitride(TiN) layer 9 is formed between the titanium silicide layer 5 and the oxide layer 6. The cause of formation of the titanium nitride layer 9 is that the RTP for forming the titanium silicide is performed under the nitrogen-filled environment. Under the nitrogen-filled environment, titanium easily reacts to nitrogen so that titanium nitride is formed.

FIG. 2b shows that the problem caused by the titanium nitride formed between the titanium silicide layer 5 and the oxide layer 6. While the screen oxide layer 7 is formed on the exposed surface of the substrate 1, the sidewall of the gate electrode is also oxidized. Since the titanium nitride is very easily oxidized, a very thick oxide layer on the sidewall portion of the titanium nitride layer 9 is formed very rapidly. Therefore, the screen oxide layer 10 formed on the sidewall of titanium nitride is thicker than that on the other portion of the gate electrode.

FIG. 2c shows the problem caused by the thick screen oxide layer 10. When the ions are doped into the silicon substrate 1 to form LDD structure, the thick screen oxide layer 10 functions as a barrier on the path of the ions, so that the source or drain is abnormally formed.

### SUMMARY OF THE INVENTION

Therefore, the present invention has been made in view of the above mentioned problem, it is an object of the present invention to provide a method for forming a semiconductor MOSFET device having polycide gate electrode by preventing the sidewall screen oxide from being abnormally formed.

According to an aspect of the present invention, there is provided a method for fabricating a MOSFET comprising a polycide gate electrode with titanium silicide on a semiconductor substrate, comprising the steps of: forming a polysilicon layer and a titanium layer on a gate insulating layer; performing a rapid thermal process for forming a titanium silicide layer under nitrogen-filled environment; and removing a titanium nitride layer, which is a byproduct formed on the titanium silicide layer during said b) step of performing the rapid thermal process.

### BRIEF DESCRIPTION OF THE DRAWINGS

A further understanding of the nature and advantage of the present invention will become apparent by reference to the remaining portions of the specification and drawings, in which:

FIGS. 1a to 1f are cross sectional views of process steps of a conventional method for fabricating a conventional MOSFET using titanium silicide;

FIGS. 2a to 2c are cross sectional views describing the problems caused by the conventional method for fabricating a conventional MOSFET shown in FIGS. 1a to 1f; and

FIGS. 3a to 3g are cross sectional views of process steps of a method for fabricating a MOSFET according to one embodiment of the present invention.

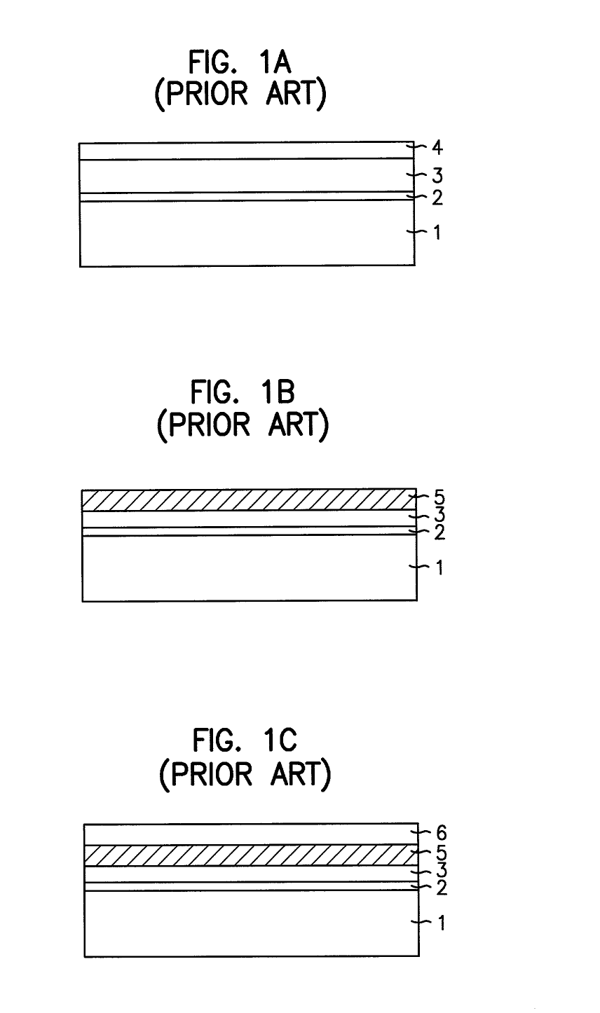

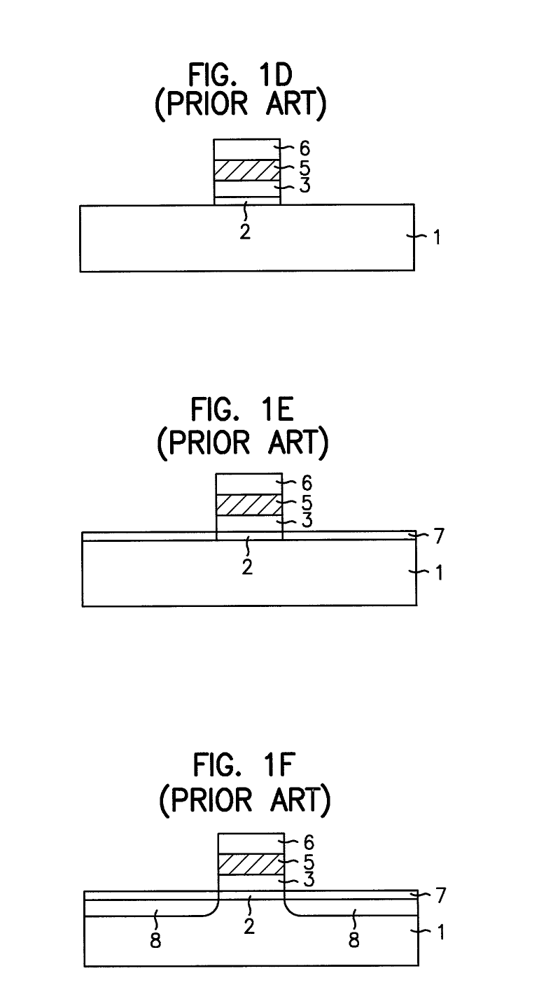

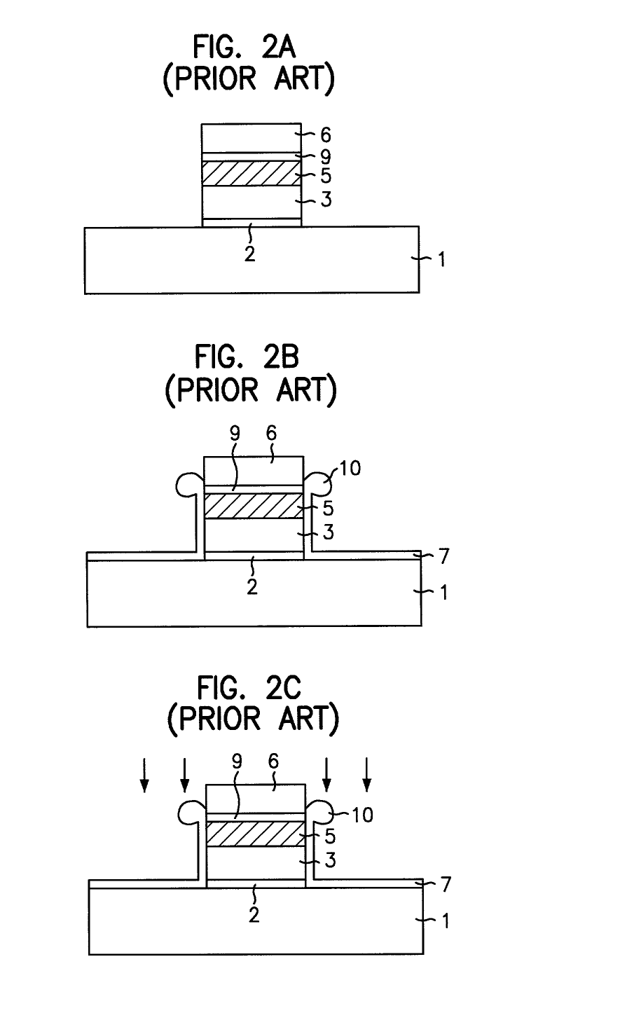

### DETAILED DESCRIPTION OF THE PREFERRED EMBODIMENT

A detailed description of an embodiment according to the present invention will be given below with reference to the attached drawings. In the drawings, the same reference numbers are used to indicate the same elements.

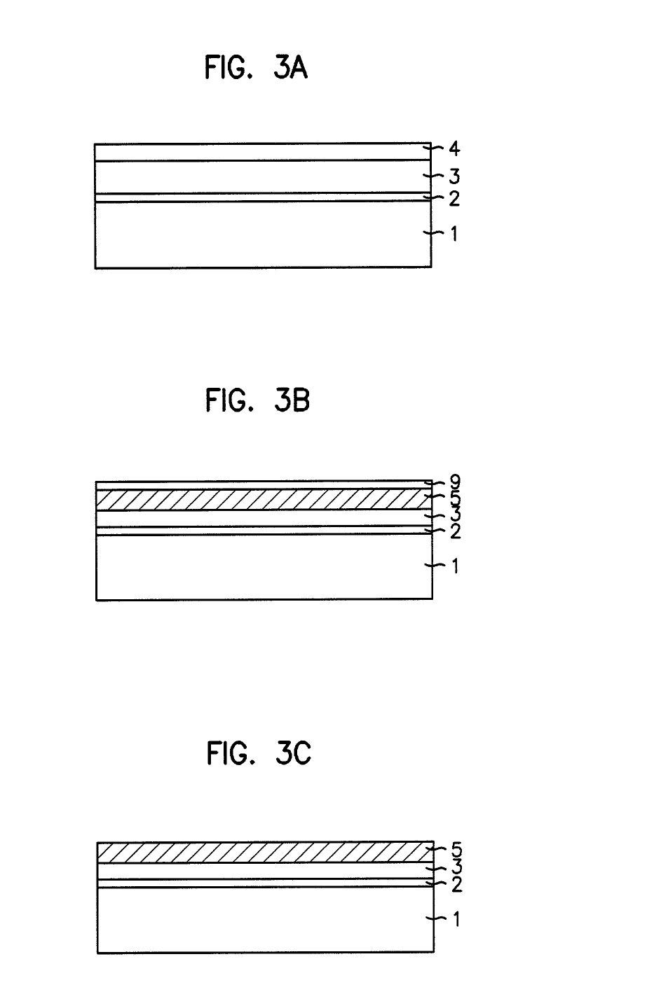

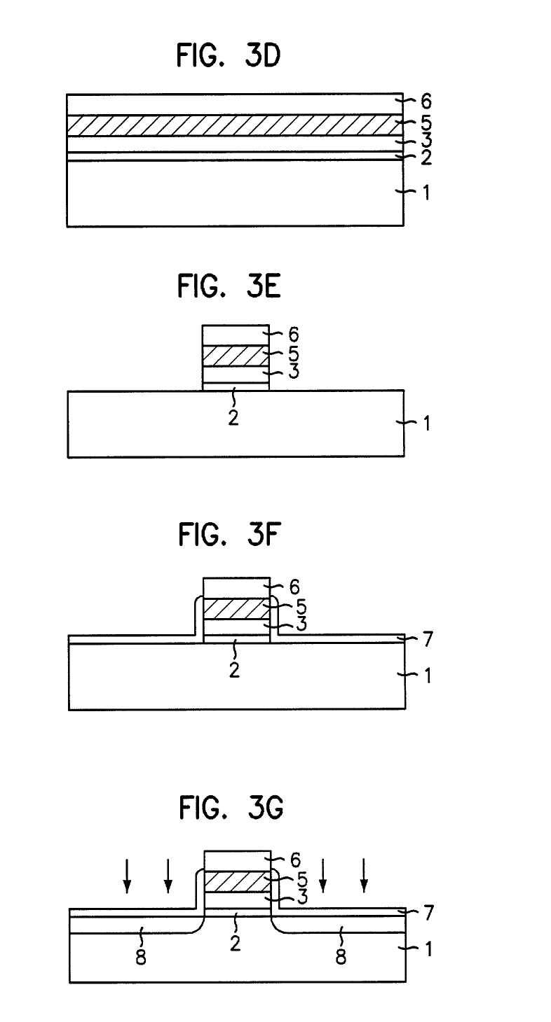

Now referring to FIGS. 3a to 3g, FIGS. 3a to 3g are cross sectional views of process steps of a method for fabricating a MOSFET according to one embodiment of the present invention. As shown in FIG. 3a, a gate oxide layer 2 is formed on a semiconductor substrate 1, a low resistance polysilicon layer 3 is formed on the gate oxide layer 2 to a thickness in the range of about 1000 to about 2000 Å by LPCVD(Low Pressure Chemical Vapor Deposition), and a titanium(Ti) layer 4 is formed on the polysilicon layer 3 to a thickness in the range of about 200 to about 1000 Å.

Then, as shown in FIG. 3b, a titanium silicide layer 5 is formed by reaction of the titanium layer 4 to the polysilicon layer 3 resulted from the RTP performed under nitrogen-filled environment. The RTP may be preferably performed for about 10 to about 30 seconds at a temperature in the range of about 800 to about 850° C. Alternatively, in order to form a very low resistance titanium silicide layer of C54 phase, the RTP can be separately performed in a first and a second stages. In the first stage, it is performed for about 10 to about 30 seconds at a temperature in the range of about 700 to about 750° C., and in the second stage, it is performed for about 10 to about 30 seconds at a temperature in the range of about 750 to about 850° C.

As mentioned above, however, a titanium nitride layer 9 is formed on the titanium silicide layer 5 because of the RTP with nitrogen environment. Therefore, as shown in FIG. 3c, the titanium nitride layer 9 is etched by diluted NH₄OH solution. The titanium silicide layer 5 is not etched by the diluted NH₄OH solution. In case the RTP is performed separately in first and second stages, the etching process may also be performed after each of the stage or performed only after the second RTP stage. Further, the dilution ratio of the NH₄OH solution may preferably be NH₄OH:H₂O₂:H₂O=1:1:5. Alternatively, diluted H₂SO₄ solution may be substituted for the NH₄OH solution. In this case, the dilution ratio of the diluted H₂SO₄ solution may be H₂SO₄:H₂O₂=3:1 to 4:1. Both solutions can be used to remove the titanium nitride layer 9 without damaging the titanium silicide layer 5.

Then, as shown in FIG. 3d, an oxide layer 6 is formed on the titanium silicide layer 5.

Further, as shown in FIG. 3e, a gate electrode is patterned by masking and etching processes, and a screen oxide layer 7 is formed on the exposed silicon substrate 1(FIG. 3f). The screen oxide layer 7 is formed to a thickness in the range of about 30 to about 100 Å at a temperature in the range of about 700 to about 850° C. According to the present invention, the screen oxide layer 7 on the sidewall of the gate electrode has uniform thickness.

Then, a low density ion doping process is performed to form LDD source or drain 8. As shown in FIG. 3g, the doping path of the ions are not obstructed by abnormally formed sidewall screen oxide, so that the LDD structure can be successfully formed.

Therefore, according to the present invention, the formation of source or drain of the LDD structure can be normally controlled, the device performance and yield are increased.

Although the preferred embodiment of the present invention has been disclosed for illustrative purposes, those skilled in the art will appreciate that various modifications, additions and substitutions are possible, without departing from the scope and the spirit of the present invention as disclosed in the accompanying claims.

What is claimed is:

1. A method for fabricating a MOSFET having a polycide gate electrode with titanium silicide on a semiconductor substrate, comprising the steps of:
a) forming a polysilicon layer and a titanium layer on a gate insulating layer;
b) performing a rapid thermal process for forming a titanium silicide layer under nitrogen-filled environment; and
c) removing a titanium nitride layer, which is a byproduct formed on the titanium silicide layer during said b) step of performing the rapid thermal process.

2. The method as claimed in claim 1, wherein the titanium nitride layer is removed with diluted NH₄OH solution.

3. The method as claimed in claim 1, wherein the titanium nitride layer is removed with diluted solution, wherein the dilution ratio of the solution is NH₄OH:H₂O₂:H₂O=1:1:5.

4. The method as claimed in claim 1, wherein the titanium nitride layer is removed with diluted H₂SO₄ solution.

5. The method as claimed in claim 1, wherein the titanium nitride layer is removed with diluted solution, wherein the dilution ratio of the solution is H₂SO₄:H₂O₂=3:1 to 4:1.

6. The method as claimed in claim 1, wherein the rapid thermal process is performed for about 10 to 30 seconds at a temperature of about 800 to 850° C.

7. The method as claimed in claim 1, wherein the rapid thermal process is separately performed in a first stage and a second stage, wherein in the first stage the rapid thermal process is performed for about 10 to 30 seconds at a temperature of about 700 to 750° C., and in the second stage the rapid thermal process is performed for about 10 to 30 seconds at a temperature of about 750 to 850° C.

8. The method as claimed in claim 7, wherein said c) step of removing the titanium nitride layer is performed after each of the first stage and the second stage of the rapid thermal process.

9. The method as claimed in claim 1, further comprising the steps of:
e) forming a mask insulating layer on the titanium silicide layer, after said c) step of removing the titanium nitride layer;
e) patterning the mask insulating layer, titanium silicide layer, the polysilicon layer and the gate insulating layer by gate masking and etching process; and
f) forming a screen insulating layer for protecting the semiconductor substrate when ions are doped to form a source or a drain.

10. The method as claimed in claim 9, wherein the titanium nitride layer is removed with diluted NH₄OH solution.

11. The method as claimed in claim 9, wherein the titanium nitride layer is removed with diluted solution, wherein the dilution ratio of the solution is NH₄OH:H₂O₂:H₂O=1:1:5.

12. The method as claimed in claim 9, wherein the titanium nitride layer is removed with diluted H₂SO₄ solution.

13. The method as claimed in claim 9, wherein the titanium nitride layer is removed with diluted solution, wherein the dilution ratio of the solution is H₂SO₄:H₂O₂=3:1 to 4:1.

14. The method as claimed in claim 9, wherein the rapid thermal process is performed for about 10 to 30 seconds at a temperature of about 800 to 850° C.

15. The method as claimed in claim 9, wherein the rapid thermal process is separately performed in a first stage and a second stage, wherein in the first stage the rapid thermal process is performed for about 10 to 30 seconds at a temperature of about 700 to 750° C., and in the second stage the rapid thermal process is performed for about 10 to 30 seconds at a temperature of about 750 to 850° C.

16. The method as claimed in claim 15, wherein said c) step of removing the titanium nitride layer is performed after each of the first stage and the second stage of the rapid thermal process.

17. The method as claimed in claim 9, the screen oxide layer is formed to a thickness of about 30 to 100 Å at a temperature of about 700 to 850° C.
